(19) United States
(12) Patent Application Publication
(10) Pub. No.: US 2015/0108001 A1
(43) Pub. Date: Apr. 23, 2015

(54) LIQUID PROCESSING JIG AND LIQUID PROCESSING METHOD

(71) Applicant: TOKYO ELECTRON LIMITED, Tokyo (JP)

(72) Inventors: Kazuo SAKAMOTO, Kumamoto (JP); Haruo IWATSU, Kumamoto (JP)

(73) Assignee: TOKYO ELECTRON LIMITED, Tokyo (JP)

(21) Appl. No.: 14/520,031

(22) Filed: Oct. 21, 2014

(30) Foreign Application Priority Data
Oct. 22, 2013 (JP) 2013-219014

(51) Int. Cl. H01L 21/67; C25D 7/12; H01L 21/02; C25F 3/12

(52) U.S. Cl. CPC H01L 21/67023; C25F 3/12; C25D 7/12; H01L 21/02068
USPC 205/80; 204/275.1; 205/640; 134/34; 137/561 R

(57) ABSTRACT

Disclosed is a liquid processing jig for performing a predetermined processing on a workpiece using a processing liquid. The liquid processing jig includes: a liquid processing unit formed on a surface of the liquid processing jig and configured to perform a predetermined processing on the workpiece by the processing liquid; a liquid supplying unit configured to supply the processing liquid to the liquid processing unit; a liquid supplying channel configured to connect the liquid supplying unit and the liquid processing unit and supply the processing liquid from the liquid supplying unit to the liquid processing unit; and a liquid discharging channel configured to discharge the processing liquid from the liquid processing unit. The liquid supplying unit, the liquid supplying channel, the liquid processing unit, and the liquid discharging channel are provided to cause the processing liquid to flow by a capillary phenomenon.

### CROSS-REFERENCE TO RELATED APPLICATIONS

This application is based on and claims priority from Japanese Patent Application No. 2013-219014 filed on Oct. 22, 2013 with the Japan Patent Office, the disclosure of which is incorporated herein in its entirety by reference.

### TECHNICAL FIELD

The present disclosure relates to a liquid processing jig which performs a predetermined processing on an object to be processed (hereinafter, referred to as a “workpiece”) using a processing liquid, and a liquid processing method using the same.

### BACKGROUND

Recently, semiconductor apparatuses require high performance and semiconductor devices are being highly integrated. Under this situation, when a semiconductor apparatus is manufactured by mounting a plurality of highly integrated semiconductor devices on a horizontal surface and connecting the semiconductor devices with wirings, a wiring length may increase so that a wiring resistance and a wiring delay may increase.

Therefore, there is proposed a three-dimensional integration technology for three-dimensionally laminating semiconductor devices. According to the three-dimensional integration technology, a plurality of electrodes having a fine diameter of, for example, 100 μm or less, so called through silicon vias (TSVs) are formed through a semiconductor wafer (hereinafter, referred to as a “wafer”) in which the rear surface of the wafer is polished so that the thickness of the wafer is reduced and a plurality of electronic circuits is formed on a front surface. In addition, vertically laminated wafers are electrically connected with each other by the through silicon vias.

Various methods of forming the above-mentioned through silicon vias have been reviewed. For example, Japanese Laid-Open Patent Publication No. 2013-108111 discloses a method of forming a through silicon via by performing, for example, electrolytic plating inside of a through hole of a wafer using a template which is provided with a flow passageway of, for example, a plating liquid. Specifically, the template is disposed to face the wafer and then the plating liquid is supplied into the through hole of the wafer from the flow passageway of the template by a capillary phenomenon. Thereafter, a voltage is applied using a template side electrode as a positive pole and a wafer side counter electrode as a negative pole and the plating processing is performed inside of the through hole so as to form the through silicon via in the through hole.

### SUMMARY

The present disclosure provides a liquid processing jig for performing a predetermined processing on a workpiece using a processing liquid. The liquid processing jig includes: a liquid processing unit formed on a surface of the liquid processing jig and configured to perform a predetermined processing on the workpiece by the processing liquid; a liquid supplying unit configured to supply the processing liquid to the liquid processing unit; a liquid supplying channel configured to connect the liquid supplying unit and the liquid processing unit and supply the processing liquid from the liquid supplying unit to the liquid processing unit; and a liquid discharging channel configured to discharge the processing liquid from the liquid processing unit. The liquid supplying unit, the liquid supplying channel, the liquid processing unit, and the liquid discharging channel are provided to cause the processing liquid to flow by a capillary phenomenon.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a vertical cross-sectional view schematically illustrating a configuration of a wafer.

FIG. 2 is a vertical cross-sectional view schematically illustrating a configuration of a template.

FIG. 3 is a plan view schematically illustrating a configuration of a liquid supplying unit.

FIG. 4 is a plan view schematically illustrating a configuration of a liquid supplying discharging unit.

FIG. 5 is a vertical cross-sectional view schematically illustrating a configuration of a template according to another exemplary embodiment.

FIG. 6 is an explanatory view illustrating that a template is disposed on a wafer.

FIG. 7 is an explanatory view illustrating that a plating liquid is supplied into a through hole through a liquid processing unit and a voltage is applied to the plating liquid.

FIG. 8 is an explanatory view illustrating that plated copper is precipitated in the through hole.

FIG. 9 is an explanatory view illustrating that a through silicon via is formed in the through hole.

FIG. 10 is a vertical cross-sectional view schematically illustrating a configuration of a template according to another exemplary embodiment.

FIG. 11 is a plan view schematically illustrating a configuration of a liquid supplying unit according to another exemplary embodiment.

FIG. 12 is a plan view schematically illustrating a configuration of a liquid supplying unit according to another exemplary embodiment.

FIG. 13 is a vertical cross-sectional view schematically illustrating a configuration of a template according to another exemplary embodiment.

FIG. 14 is a vertical cross-sectional view schematically illustrating a configuration of a template according to another exemplary embodiment.

FIG. 15 is a vertical cross-sectional view schematically illustrating a configuration of a template according to another exemplary embodiment.

FIG. 16 is an explanatory view illustrating that a template is disposed on a wafer according to another exemplary embodiment.

FIG. 17 is an explanatory view illustrating that a through hole is formed by etching a wafer according to another exemplary embodiment.

FIG. 18 is an explanatory view illustrating that a surface of the wafer is cleansed according to another exemplary embodiment.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

The plating processing is generally performed while agitating the plating liquid so that ions are stably supplied to the negative pole. However, according to the method disclosed in Japanese Laid-Open Patent Publication No. 2013-108111, even though the plating liquid is supplied into the through hole of the wafer from the flow passageway of the template, discharging of the plating liquid is not considered. In this case, the plating liquid stays in the through hole and ions in the plating liquid are reduced as the plated copper is precipitated. As a result, the processing is inefficiently performed.

Japanese Laid-Open Patent Publication No. 2013-108111 discloses a method of performing a processing other than the plating processing on a wafer, using a processing liquid other than the plating liquid, for example, an etching liquid is. However, since the above-mentioned problem occurs regardless of which one of the processings, that is, since the processing liquid is not appropriately discharged, it is difficult to efficiently perform the processing. Therefore, there is a need for improvement of the liquid processing.

The present disclosure has been made in an effort to appropriately solve the problems as described above and is to supply and discharge a processing liquid in relation to a workpiece and appropriately process the workpiece.

An aspect of the present disclosure provides a liquid processing jig for performing a predetermined processing on a workpiece using a processing liquid. The liquid processing jig includes: a liquid processing unit formed on a surface of the liquid processing jig and configured to perform a predetermined processing on the workpiece by the processing liquid; a liquid supplying unit configured to supply the processing liquid to the liquid processing unit; a liquid supplying channel configured to connect the liquid supplying unit and the liquid processing unit and supply the processing liquid from the liquid supplying unit to the liquid processing unit; and a liquid discharging channel configured to discharge the processing liquid from the liquid processing unit. The liquid supplying unit, the liquid supplying channel, the liquid processing unit, and the liquid discharging channel are provided to cause the processing liquid to flow by a capillary phenomenon.

According to the present disclosure, since the liquid supplying channel and the liquid discharging channel are connected to the liquid processing unit, a clean and fresh processing liquid is always supplied from the liquid supplying channel to the liquid processing unit and the processing liquid is discharged from the liquid discharging channel without staying in the liquid processing unit. Therefore, the workpiece may be appropriately processed in the liquid processing unit. Further, the processing liquid is caused to flow from the liquid supplying unit to the liquid discharging channel through the liquid supplying channel and the liquid processing unit only by the capillary phenomenon. That is, when the processing liquid is caused to flow, no driving unit, such as a pump, is required. Therefore, the workpiece may be efficiently processed using the liquid processing jig.

The liquid processing jig may further include a liquid discharging unit connected to one end of the liquid discharging channel and configured to discharge the processing liquid from the liquid processing unit. The liquid discharging unit has a predetermined volume accommodating the processing liquid and absorbs the processing liquid through the liquid discharging channel by the capillary phenomenon.

The liquid discharging unit may have an extending groove or tube. In addition, the liquid discharging unit may have a porous body.

The liquid processing jig may further include an electrode configured to apply a voltage to the processing liquid of the liquid processing unit. The predetermined processing performed in the liquid processing unit may be an electrolytic processing.

The liquid processing unit may include a hydrophilic region having hydrophilicity.

The liquid supplying unit may continuously supply different processing liquids.

The liquid supplying channel may have a tube which extends the liquid processing jig at least in a thickness direction or a groove which extends in a plane direction of the liquid processing jig.

A plurality of liquid supplying channels may be provided.

The liquid discharging channel may have a tube which extends the liquid processing jig at least in a thickness direction or a groove which extends in a plane direction of the liquid processing jig.

A plurality of liquid discharging channels may be provided.

Another aspect of the present disclosure provides a liquid processing method for performing a predetermined processing on a processing region of a workpiece using a liquid processing jig. The liquid processing jig includes: a liquid processing unit formed on a surface of the liquid processing jig and configured to perform a predetermined processing on the workpiece by the processing liquid; a liquid supplying unit configured to supply the processing liquid to the liquid processing unit; a liquid supplying channel configured to connect the liquid supplying unit and the liquid processing unit and supply the processing liquid from the liquid supplying unit to the liquid processing unit; and a liquid discharging channel configured to discharge the processing liquid from the liquid processing unit. The liquid processing method includes: disposing the liquid processing jig such that the liquid processing unit faces the processing region of the workpiece; and causing a processing liquid to flow from the liquid supplying unit to the liquid discharging channel by a capillary phenomenon so as to perform the predetermined processing on the workpiece by the processing liquid while the processing liquid is flowing.

The liquid processing jig may further include: the liquid processing jig may further include: a liquid discharging unit which is connected to one end of the liquid discharging channel and discharges the processing liquid from the liquid processing unit. In the processing process, the liquid discharging unit may have a predetermined volume which accommodates the processing liquid and absorbs the processing liquid through the liquid discharging channel by the capillary phenomenon.

The liquid processing jig may further include: an electrode configured to apply a voltage to the processing liquid of the liquid processing unit. The predetermined processing performed in the processing process is an electrolytic processing.

The liquid processing unit may include a hydrophilic region having hydrophilicity.

In the processing process, different processing liquids may be continuously supplied from the liquid supplying unit so that different processings are continuously performed in the liquid processing unit.

According to the present disclosure, the processing liquid may be appropriately supplied and discharged to and from the workpiece and the workpiece may be appropriately processed.

Hereinafter, an exemplary embodiment of the present disclosure will be described. In the present exemplary embodiment, as a processing performed on a wafer as a workpiece according to the present disclosure, a plating processing for forming a through silicon via in a through hole formed on the wafer will be described together with configurations of a wafer used for the plating processing and a template serving as a liquid processing jig. Further, in the drawings used in the following description, a size of each component does not necessarily correspond to an actual size in order to ensure easy understanding of the technology.

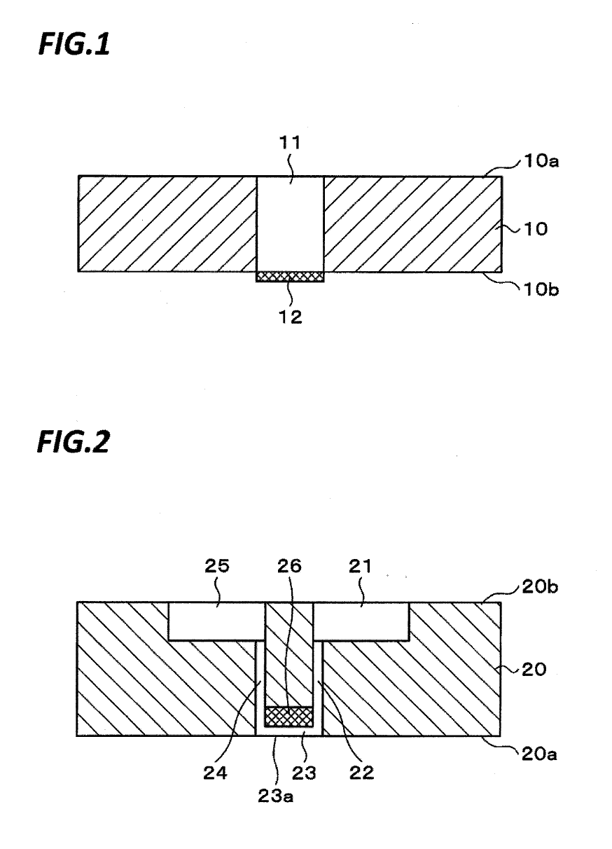

First, configurations of a wafer and a template used for a plating processing according to the present exemplary embodiment will be described. As illustrated in FIG. 1, a through hole 11 is formed in the wafer 10 extending through the wafer 10 from a front surface 10a to a rear surface 10b of the wafer 10 in a thickness direction. In the exemplary embodiment, the inside of the through hole 11 corresponds to a processing area of the present disclosure. A wafer side electrode 12 corresponding to a template side electrode 26 of a template 20 to be described below is provided at a rear surface 10b side of the through hole 11. Further, even though only one through hole 11 is illustrated in FIG. 1, a plurality of through holes 11 is actually formed on the wafer 10. Further, a plurality of wafer side electrodes 12 is correspondingly provided.

A device layer (not illustrated) including an electronic circuit or a wiring is formed on the rear surface 10b of the wafer 10. The above-described wafer side electrode 12 is disposed on the device layer. Further, the wafer 10 has a reduced thickness and a supporting substrate (not illustrated) is provided on the rear surface 10b of the wafer 10 to support the thin wafer 10. A silicon wafer or a glass substrate is used for the supporting substrate. Further, the wafer side electrode 12 may be provided on the supporting substrate.

The template 20 illustrated in FIG. 2 has a substantially disk shape and has the same shape as the wafer 10 as seen in a plan view. Silicon carbide (SiC) is used for the template 20.

In the template 20, a liquid supplying unit 21, a liquid supplying channel 22, a liquid processing unit 23, a liquid discharging channel 24, and a liquid discharging unit 25 are provided to be connected in this order. The liquid processing unit 23 is formed on the front surface 20a of the template 20. The liquid supplying unit 21 and the liquid discharging unit 25 are formed on the rear surface 20b of the template 20. The liquid supplying channel 22 and the liquid discharging channel 24 are formed in the template 20. Further, FIG. 2 illustrates the template 20 in the state where the front surface 20a of the template 20 is positioned at the bottom side and the rear surface 20b of the template 20 is positioned at the bottom side.

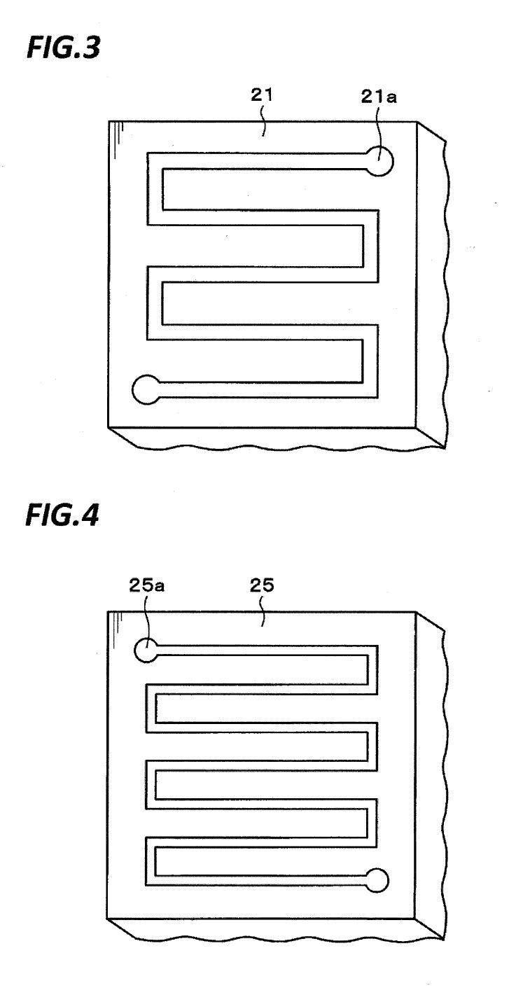

As for the liquid supplying unit 21, a tank capable of reserving the plating liquid is used to supply the plating liquid. In the present exemplary embodiment, as illustrated in FIG. 3, the inside of the liquid supplying unit 21 has a narrow groove structure so that the liquid meanders therethrough. In this case, the plating liquid is supplied from a liquid supplying port 21a. The liquid supplying unit 21 is connected to the liquid supplying channel 22 and the plating liquid meandering in the liquid supplying unit 21 enters the liquid supplying channel 22. The liquid supplying channel 22 is a narrow tube which extends in the thickness direction of the template 20 as illustrated in FIG. 2 and is connected to the liquid processing unit 23. Further, a mixed liquid in which copper sulfate and sulfuric acid are dissolved is used as the plating liquid. When the portion extending from the liquid supplying port 21a to the liquid processing unit 23 is configured by a narrow groove or a narrow tube, the capillary phenomenon is induced to the plating liquid existing in the inside thereof. Therefore, without applying an external force using a pump, the plating liquid may be conveyed to the liquid processing unit 23. Further, in the present exemplary embodiment, the inside of the liquid supplying unit 21 has a narrow groove structure in which the liquid meanders. However, the configuration of the inside of the liquid supplying unit 21 may be arbitrarily designed without being limited thereto.

The liquid processing unit 23 includes an opening 23a opened in the front surface 20a of the template 20. When the template 20 is disposed at the front surface 10a side of the wafer 10 as it will be described below, the opening 23a is formed at a position where the plating liquid is supplied to/discharged from the through hole 11 of the wafer 10. That is, in the liquid processing unit 23, the plating liquid supplied from the liquid supplying channel 22 is supplied to the through hole 11 of the wafer 10 through the opening 23a and the plating processing is performed by the plating liquid. Further, the plating liquid is discharged to the liquid discharging channel 24 through the opening 23a.

The liquid discharging channel 24 is a narrow tube which is connected to the liquid processing unit 23 and elongated in the thickness direction of the template 20 to be connected to the liquid discharging unit 25.

As the liquid discharging unit 25, a tank capable of reserving the plating liquid is used so as to discharge the plating liquid. The liquid discharging unit 25 has a predetermined volume that may accommodate the plating liquid. In the present exemplary embodiment, as illustrated in FIG. 4, the liquid discharging unit 25 is configured by a narrow groove through which the liquid meanders. As described above, the portion from the liquid discharging channel 24 to the liquid discharging unit 25 is configured by a narrow groove or a narrow tube so that the capillary phenomenon is induced to the plating liquid existing therein. Therefore, without using an external force of, for example, a pump, the processing liquid provided for the processing in the liquid processing unit 23 may be discharged. In the liquid discharging unit 25, the plating liquid slowly flows in the meandering flow passageway so that a new plating liquid is supplied to the liquid processing unit 23 and the plating liquid is discharged from the liquid processing unit 23 after the processing. As described above, since the new and fresh plating liquid is always supplied to the liquid processing unit 23 and the plating liquid does not stay, the plating processing may be appropriately performed. Further, in the present exemplary embodiment, the inside of the liquid discharging unit 25 has a meandering narrow groove structure. However, the configuration of the inside of the liquid discharging unit 25 may be arbitrarily designed without being limited thereto.

As illustrated in FIG. 2, the template side electrode 26 is provided in the template 20 so as to apply a voltage to the plating liquid of the liquid processing unit 23. The template side electrode 26 is disposed above the liquid processing unit 23 and between the liquid supplying channel 22 and the liquid discharging channel 24.

Next, descriptions will be made on configurations such as, for example, sizes of the liquid supplying unit 21, the liquid supplying channel 22, the liquid processing unit 23, the liquid discharging channel 24, and the liquid discharging unit 25 in the template 20.

First, the liquid supplying unit 21, the liquid supplying channel 22, the liquid processing unit 23, the liquid discharging channel 24, and the liquid discharging unit 25 are designed such that the plating liquid is caused to flow from the liquid supplying unit 21 to the liquid discharging unit 25 by the capillary phenomenon.

As described above, since the plating liquid is caused to flow by the capillary phenomenon between the liquid supplying unit 21 and the liquid discharging unit 25, a diameter of the flow passageway (the liquid supplying channel 22, the liquid processing unit 23, and the liquid discharging channel 24) from the liquid supplying port 21a of the liquid supplying unit 21 to a liquid discharging port 25a of the liquid discharging unit 25 gradually decreases. In the meantime, even when the diameter of the liquid discharging channel 24 is small, the flow rate of the plating liquid in the liquid discharging channel 24 is required to be equal to a flow rate of the plating liquid in the liquid supplying channel 22. That is, the surface area in the liquid discharging channel 24 is required to be equal to the surface area in the liquid supplying channel 22.

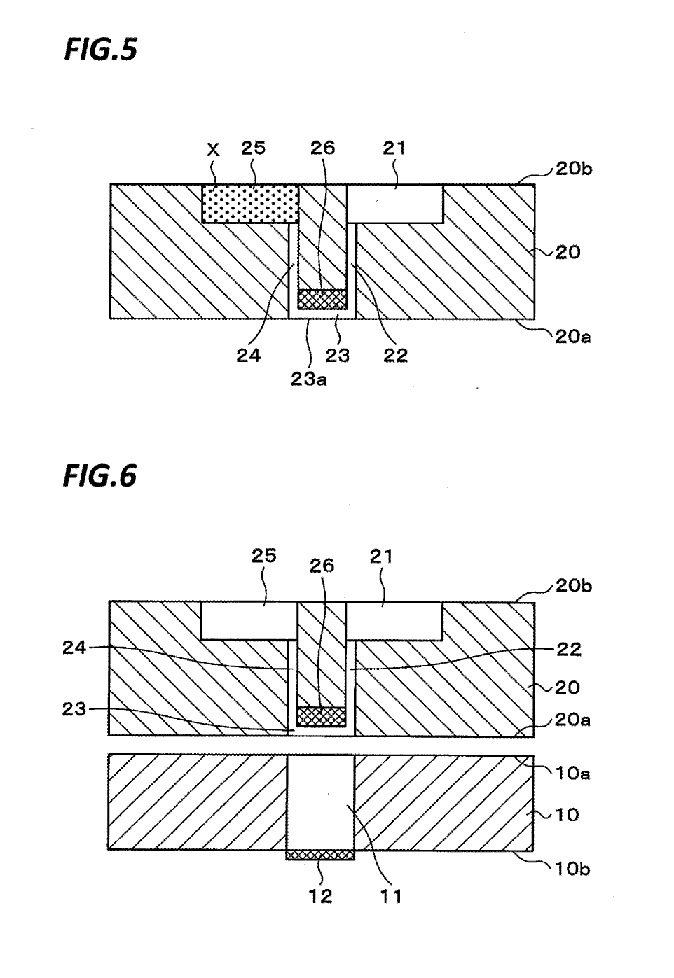

In the present exemplary embodiment, the liquid discharging unit 25 is formed by the meandering flow passageway, but is not limited thereto. As illustrated in FIG. 5, the liquid discharging unit 25 may be configured by a porous body X. The capillary phenomenon acts on the plating liquid which enters the porous body X through the liquid discharging channel 24. As if a sponge absorbs water, the porous body X absorbs the plating liquid, so that the plating liquid is drawn up from the liquid discharging unit 25.

Sizes of the liquid supplying unit 21, the liquid supplying channel 22, the liquid processing unit 23, the liquid discharging channel 24, and the liquid discharging unit 25 are determined based on the design concept as described above. Specific sizes may be calculated using a known Laplace Equation or derived by performing, for example, a simulation or an experiment.

Next, descriptions will be made on the plating processing using the wafer 10 and the template 20 configured as described above.

First, as illustrated in FIG. 6, the template 20 is disposed at the front surface 10a side of the wafer 10. In this case, the position of the template 20 is adjusted such that the through hole 11 faces the liquid processing unit 23. FIG. 6 illustrates a gap between the template 20 and the wafer 10. In practice, however, the gap is very small and the plating liquid supplied from the liquid processing unit 23 may enter the inside of the through hole 11 as it is. This will be described below.

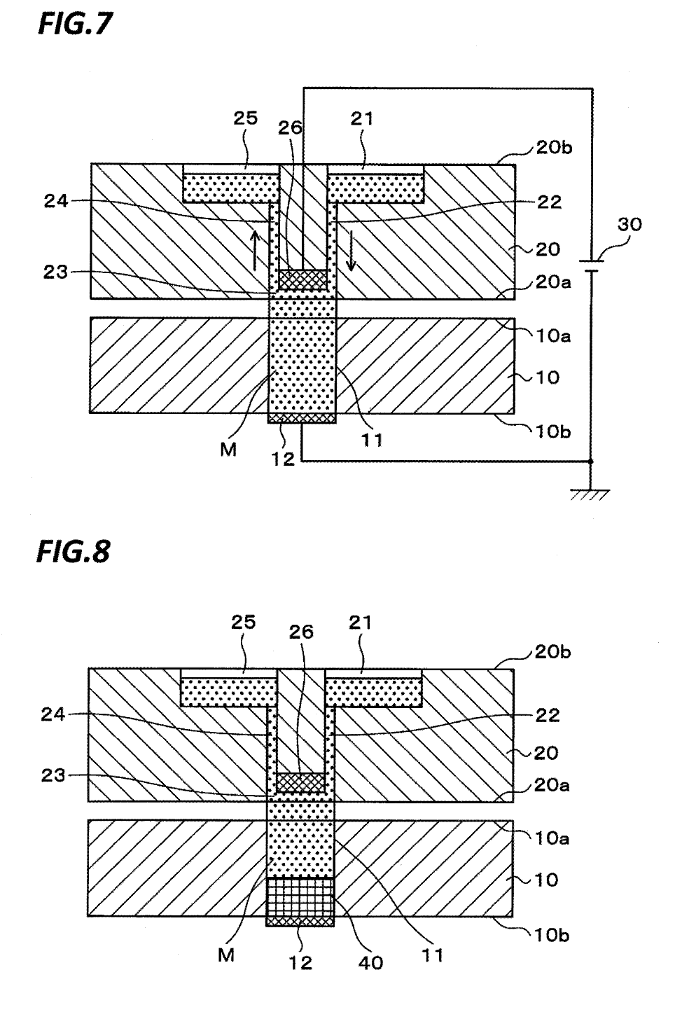

As illustrated in FIG. 7, a DC power supply 30 is connected to the wafer side electrode 12 and the template side electrode 26. The wafer side electrode 12 is connected to the negative pole side of the DC power supply 30. The template side electrode 26 is connected to the positive pole side of the DC power supply 30. Further, the DC power supply 30 is used as a common power supply for a plurality of wafer side electrodes 12 and a plurality of template side electrodes 26 in the template 20.

Thereafter, the plating liquid M is supplied to the liquid supplying unit 21 and caused to flow from the liquid supplying unit 21 to the liquid discharging unit 25 by the capillary phenomenon. In this case, the plating liquid M supplied from the liquid supplying channel 22 to the liquid processing unit 23 is supplied to the through hole 11 of the wafer 10 through the opening 23a. The through hole 11 is filled with the plating solution M.

Next, a voltage is applied to the plating liquid M by the DC power supply 30 in which the template side electrode 26 serves as the positive pole and the wafer side electrode 12 serves as the negative pole. As a result, electrolytic plating is performed on the plating liquid M in the through hole 11 and plated copper 40 is precipitated in the through hole 11 as illustrated in FIG. 8.

Next, after the plating processing is performed in the through hole 11, the plating solution M is discharged to the liquid discharging channel 24 through the opening 23a. As described above, clean and fresh plating liquid M is always continuously supplied so that the plating liquid M does not stay in the liquid processing unit 23. Therefore, the plated copper 40 may be uniformly precipitated in the through hole 11.

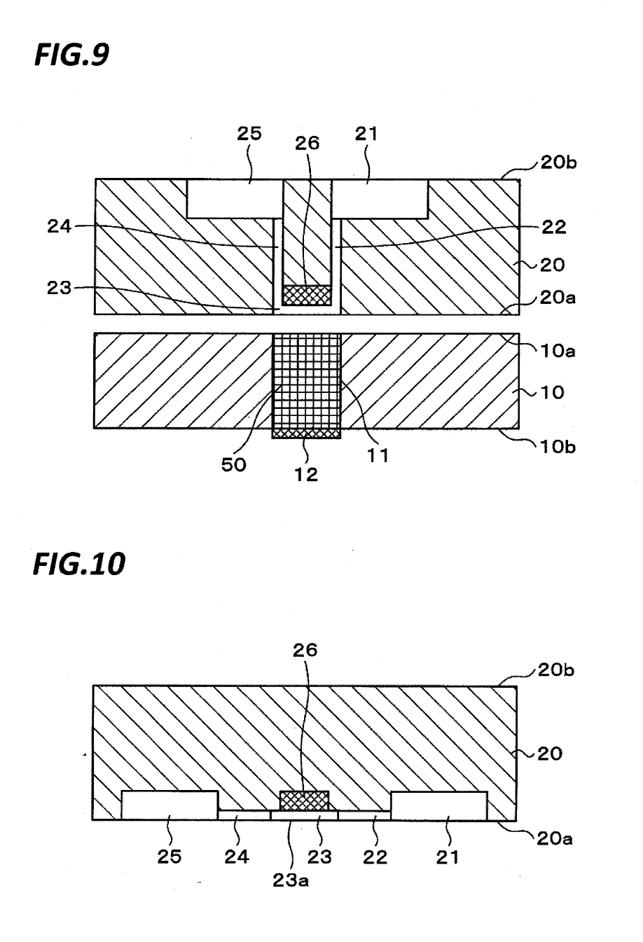

By continuously performing the plating processing, the plated copper 40 is grown so as to form a through silicon via 50 in the through hole 11 as illustrated in FIG. 9.

According to the above-described exemplary embodiment, since the liquid supplying channel 22 and the liquid discharging channel 24 are connected to the liquid processing unit 23 in the template 20, clean and fresh processing liquid is always supplied from the liquid supplying channel 22 to the liquid processing unit 23 and the plating liquid M is discharged from the liquid discharging channel 24 without staying in the liquid processing unit 23. Therefore, the plating processing in the liquid processing unit 23 may be appropriately performed.

In the template 20, the plating liquid M is caused to flow from the liquid supplying unit 21 to the liquid discharging unit 25 only by the capillary phenomenon. That is, when the plating liquid M is caused to flow, no driving unit, such as a pump, is required. Therefore, the plating processing may be efficiently performed using the template 20.

As described above, when the plating liquid M is caused to flow by the capillary phenomenon, the plating liquid M may be supplied to the liquid processing unit 23 until the plating liquid M in the liquid supplying unit 21 is completely eliminated. Therefore, the plating processing may be more efficiently performed. Further, when the plating liquid M is completely eliminated the plating liquid processing is terminated. Thus, it may be properly determined when the plating processing is terminated.

The liquid supplying channel 22 and the liquid discharging channel 24 are designed such that the surface area of the inside of the liquid supplying channel 22 and the surface area of the inside of the liquid discharging channel 24 are equal to each other so that a flow rate of the plating liquid M circulating between the liquid supplying channel 22 and the liquid discharging channel 24 may be secured with an appropriate flow rate.

In the template 20 according to the above-described exemplary embodiment, the liquid supplying unit 21, the liquid supplying channel 22, the liquid processing unit 23, the liquid discharging channel 24, and the liquid discharging unit 25 may have various configurations without being limited to the above exemplary embodiment.

For example, even though the liquid supplying unit 21 and the liquid discharging unit 25 are provided on the rear surface 20b of the template 20, the liquid supplying unit 21 and the liquid discharging unit 25 may be provided on the front surface 20a of the template 20, as illustrated in FIG. 10. In this case, the liquid supplying channel 22 and the liquid discharging channel 24 may have a narrow groove structure rather than the narrow tube structure.

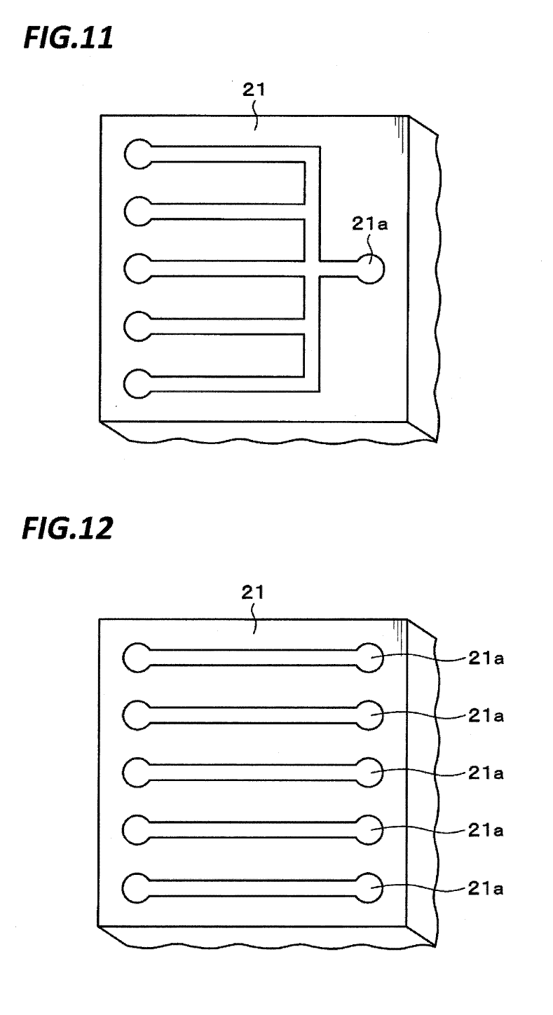

In the liquid supplying unit 21, as illustrated in FIG. 11, the narrow groove may be divided into a plurality of narrow grooves and a plurality of liquid supplying channels 22 connected to the divided narrow grooves may be provided. Alternatively, as illustrated in FIG. 12, a plurality of liquid supplying ports 21a of the liquid supplying unit 21 may be provided and a plurality of narrow grooves and a plurality of liquid supplying channels 22 may be correspondingly provided. As described above, when the plurality of liquid supplying channels 22 is provided, the plating liquid M is supplied from one liquid supplying unit 21 to the plurality of liquid processing units 23 so that the plating processing may be efficiently performed.

Similarly, for example, in the liquid discharging unit 25, the narrow groove may be divided into a plurality of narrow grooves and a plurality of liquid discharging channels 24 connected to the divided discharging grooves may be provided. Alternatively, a plurality of liquid discharging ports 25a of the liquid discharging unit 25 may be provided and a plurality of liquid discharging channels 24 and a plurality of discharging ports may be correspondingly provided. As described above, when the plurality of liquid discharging channels 24 is provided, the plating liquid M is discharged from the plurality of liquid processing units 23 to one liquid discharging unit 25 so that the plating processing may be efficiently performed.

As described above, even if the configurations of the liquid supplying unit 21, the liquid supplying channel 22, the liquid processing unit 23, the liquid discharging channel 24, and the liquid discharging unit 25 are changed, the same effect as the above-described exemplary embodiment may be achieved when the plating liquid M is caused to flow between the liquid supplying unit 21 and the liquid discharging unit 25 by the capillary phenomenon as described above.

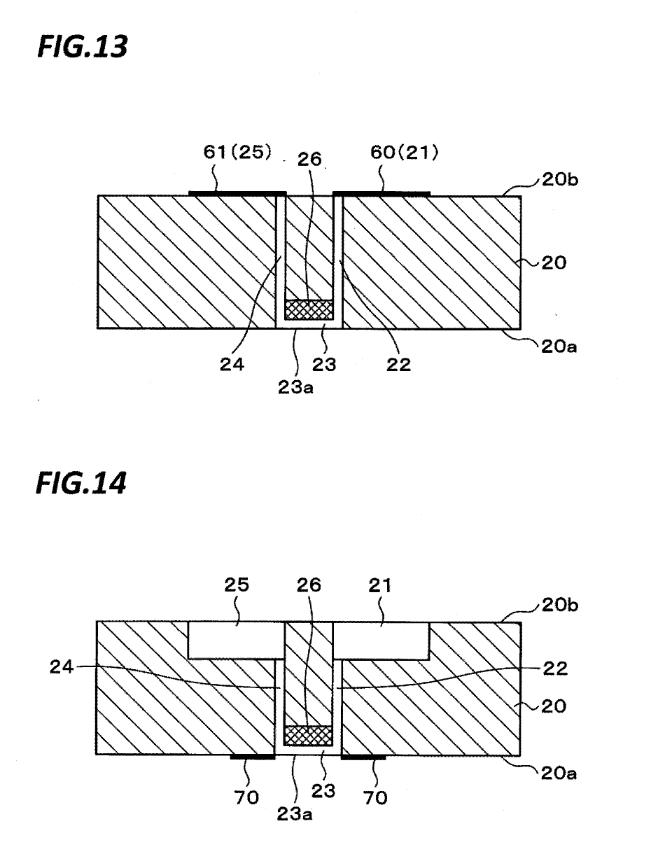

In the template 20 according to the above exemplary embodiment, the liquid supplying unit 21 and the liquid discharging unit 25 are tanks which reserves the plating liquid M, but are not limited thereto. For example, as illustrated in FIG. 13, a hydrophilic region 60 may be formed in a place where the liquid supplying unit 21 is formed and a hydrophilic region 61 may be formed in a place where the liquid discharging unit 25 is formed. In this case, the plating liquid M supplied into the hydrophilic region 60 does not leak to the outside of the hydrophilic region 60 and the hydrophilic region 60 serves as the liquid supplying unit 21. Further, the plating liquid M discharged onto the hydrophilic region 61 does not leaks to the outside of the hydrophilic region 61 and the hydrophilic region 61 serves as the liquid discharging unit 25. Also in this case, while the plating liquid M spreads on the hydrophilic region 61, the clean and fresh plating liquid M is continuously supplied to the liquid processing unit 23.

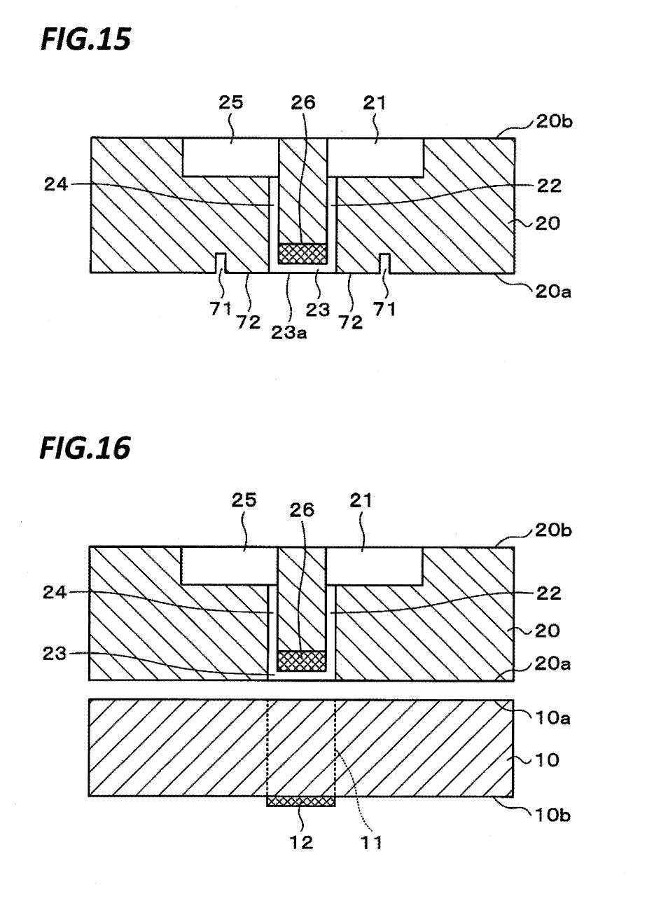

In the template 20 according to the above-described exemplary embodiment, the liquid processing unit 23 may include a hydrophilic region. For example, as illustrated in FIG. 14, on the front surface 20a of the template 20, a hydrophilic region 70 having hydrophilicity may be formed around the opening 23a. Alternatively, for example, on the front surface 20a of the template 20 as illustrated in FIG. 15, a circular groove 71 may be formed outside of the opening 23a. In this case, the hydrophilic region 72 between the opening 23a and the groove 71 may serve as a hydrophilic region having hydrophilicity by a pinning effect of the groove 71 on appearance, as compared with a region outside the hydrophilic region 72. Even when the liquid processing unit 23 includes any of the hydrophilic regions 70 and 72, the plating liquid M does not leaks to the outside of the hydrophilic regions 70 and 72 when the plating processing is performed. Therefore, the plating processing may be more appropriately performed.

In the above exemplary embodiment, even though it is described that the plating processing is performed as a predetermined processing for the wafer 10, the present disclosure may be applied to various liquid processings. For example, the present disclosure may be applied to other electric field processings such as an etching processing and the present disclosure may be applied to liquid processings other than the electrolytic processing such as, for example, a cleaning processing.

In the above-descried exemplary embodiment, although the descriptions have been made on a case where a single plating processing is performed using the template 20, different processing liquids may be continuously supplied from the liquid supplying unit 21 to the liquid processing unit 23 so as to continuously perform different processings in the liquid processing unit 23.

In the following description, descriptions will be made on a case where an etching processing to form a through hole 11 in the wafer 10, the above-described plating processing to form the through silicon via 50 in the through hole 11, and the cleaning processing to wash the wafer 10 formed with a through silicon via 50 are continuously performed.

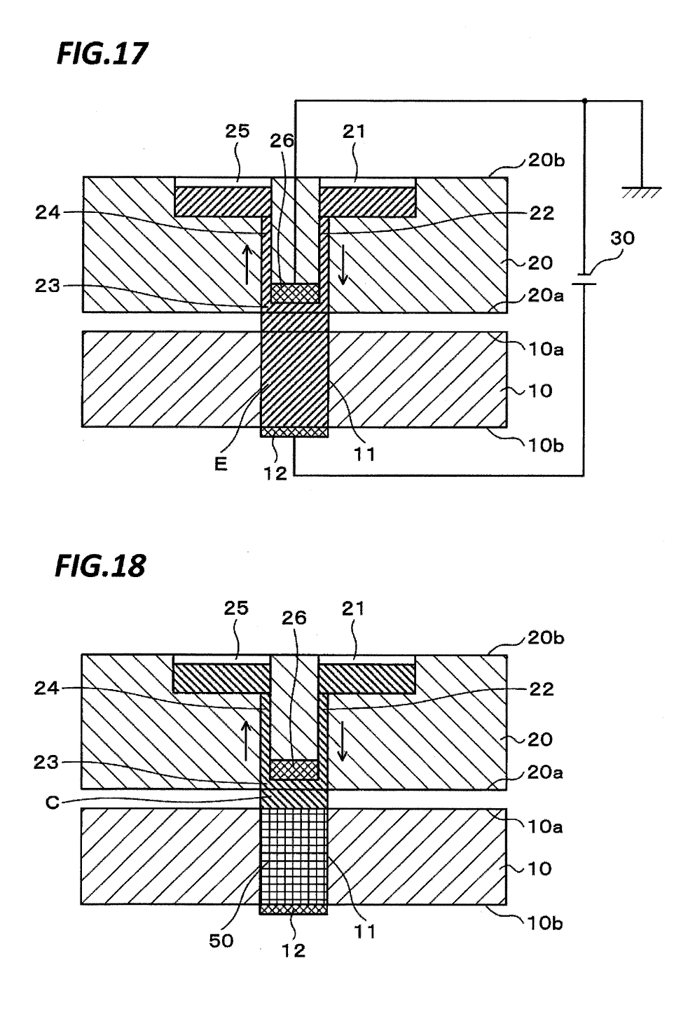

First, as illustrated in FIG. 16, the template 20 is disposed to at the front surface 10a side of the wafer 10. In this case, the position of the template 20 is adjusted such that a place (a portion represented by the dotted line in FIG. 16) where the through hole 11 is formed faces the liquid processing unit 23. As illustrated in FIG. 17, the wafer side electrode 12 is connected to the positive pole side of the DC power supply 30 and the template side electrode 26 is connected to the negative pole side of the DC power supply 30. Further, in the present exemplary embodiment, the position in the wafer 10 where the through hole 11 is formed corresponds to a processing region in the present disclosure.

Thereafter, an etching liquid E as a processing liquid is supplied to the liquid supplying unit 21 and caused to flow from the liquid supplying unit 21 to the liquid discharging unit 25 by the capillary phenomenon. In this case, the etching liquid E supplied from the liquid supplying channel 22 to the liquid processing unit 23 is supplied to the location (the processing region) where the through hole 11 of the wafer 10 is formed, through the opening 23a. Further, as for the etching liquid E, a mixed liquid of hydrofluoric acid and isopropyl alcohol (HF/IPA) or a mixed liquid of hydrofluoric acid and ethanol is used.

Thereafter, a voltage is applied to the etching liquid E by the DC power supply 30 in which the template side electrode 26 is set as a negative pole and the wafer side electrode 12 is set as a positive pole. Then, the electric field etching of the wafer 10 is performed by the etching liquid E and the etching liquid E enters into the wafer 10 while etching the wafer 10. Further, as illustrated in FIG. 6, the through hole 11 which penetrates the wafer 10 in the thickness direction is formed.

In the etching processing, since the etching liquid E is caused to flow from the liquid supplying unit 21 to the liquid discharging unit 25 by the capillary phenomenon, the etching liquid E may be supplied to the liquid processing unit 23 until the etching liquid E in the liquid supplying unit 21 is completely eliminated. In other words, when the through hole 11 is formed in the wafer 10, the etching liquid E is completely eliminated in the liquid supplying unit 21. Therefore, a subsequent plating processing may be continuously performed without cleaning the flow passageway from the liquid supplying unit 21 to the liquid discharging unit 25.

When the etching processing is completed, the plating liquid M is supplied to the liquid supplying unit 21 and the plating processing is performed in the liquid processing unit 23. Further, the through silicon via 50 is formed in the through hole 11. Since the plating processing to form the through silicon via 50 is the same as the plating processing of the exemplary embodiment, a detailed description of the plating processing to form the through silicon via will be omitted.

Even in this plating processing, the plating liquid M may be supplied to the liquid processing unit 23 until the plating liquid M in the liquid supplying unit 21 is completely eliminated. In other words, when the through silicon via 50 is formed in the through hole 11, the plating liquid M is completely eliminated in the liquid supplying unit 21.

When the plating processing is completed, the cleaning processing of the front surface 10a of the wafer 10 is continuously performed. Further, in the present exemplary embodiment, a region on the through silicon via 50 of the wafer 10 corresponds to a processing region in the present disclosure.

Specifically, as illustrated in FIG. 18, cleaning liquid C, for example, pure water serving as the processing liquid is supplied to the liquid supplying unit 21, as illustrated in FIG. 18. As a result, the cleaning liquid C is caused to flow from the liquid supplying unit 21 to the liquid discharging unit 25 by the capillary phenomenon. In this case, the cleaning liquid C supplied from the liquid supplying channel 22 to the liquid processing unit 23 is supplied onto the through silicon via 50 through the opening 23a. The front surface of the through silicon via 50 is cleaned by the cleaning liquid C and the front surface 10a of the wafer 10 is cleaned.

According to the present exemplary embodiment, the etching liquid E, the plating liquid M, and the cleaning liquid C supplied to the liquid supplying unit 21 do not remain in the liquid supplying unit 21 when the etching processing, the plating processing, and the cleaning processing are completed, respectively. Therefore, the processing liquid used in each of the processings is not mixed with the processing liquid used in the subsequent processing and even when different processings are continuously performed, the individual processings are appropriately performed.

Even in the etching processing or the cleaning processing other than the plating processing, the etching liquid E or the cleaning liquid C may be caused to flow by the capillary phenomenon so that the same effect as the plating processing according to the exemplary embodiment may be achieved.

In the exemplary embodiment, the plating processing is performed in the through hole 11 to form the through silicon via 50. However, the plating processing may be performed on the through silicon via 50 to form a bump. Further, the electric field processing to which the present disclosure may be applied may be an insulating layer formation processing to form an insulating layer in the through hole 11 of the wafer 10 using, for example, polyimide solution for electro-deposition, without being limited to the plating processing or the etching processing.

From the foregoing description, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A liquid processing jig for performing a predetermined processing on a workpiece using a processing liquid, the liquid processing jig comprising:
a liquid processing unit formed on a surface of the liquid processing jig and configured to perform a predetermined processing on the workpiece by the processing liquid;
a liquid supplying unit configured to supply the processing liquid to the liquid processing unit;
a liquid supplying channel configured to connect the liquid supplying unit and the liquid processing unit and supply the processing liquid from the liquid supplying unit to the liquid processing unit; and
a liquid discharging channel configured to discharge the processing liquid from the liquid processing unit,
wherein the liquid supplying unit, the liquid supplying channel, the liquid processing unit, and the liquid discharging channel are provided to cause the processing liquid to flow by a capillary phenomenon.

2. The liquid processing jig of claim 1, further comprising:
a liquid discharging unit connected to one end of the liquid discharging channel and configured to discharge the processing liquid from the liquid processing unit,
wherein the liquid discharging unit has a predetermined volume accommodating the processing liquid and absorbs the processing liquid through the liquid discharging channel by the capillary phenomenon.

3. The liquid processing jig of claim 2, wherein the liquid discharging unit has an extending groove or tube.

4. The liquid processing jig of claim 2, wherein the liquid discharging unit has a porous body.

5. The liquid processing jig of claim 1, further comprising:
an electrode configured to apply a voltage to the processing liquid of the liquid processing unit,
wherein the predetermined processing performed in the liquid processing unit is an electrolytic processing.

6. The liquid processing jig of claim 1, wherein the liquid processing unit includes a hydrophilic region having hydrophilicity.

7. The liquid processing jig of claim 1, wherein the liquid supplying unit continuously supplies different processing liquids.

8. The liquid processing jig of claim 1, wherein the liquid supplying channel has a tube which extends the liquid processing jig at least in a thickness direction or a groove which extends in a plane direction of the liquid processing jig.

9. The liquid processing jig of claim 1, wherein a plurality of liquid supplying channels is provided.

10. The liquid processing jig of claim 1, wherein the liquid discharging channel has a tube which extends the liquid processing jig at least in a thickness direction or a groove which extends in a plane direction of the liquid processing jig.

11. The liquid processing jig of claim 1, wherein a plurality of liquid discharging channels is provided.

12. A liquid processing method for performing a predetermined processing on a processing region of a workpiece using a liquid processing jig, wherein the liquid processing jig includes:
a liquid processing unit formed on a surface of the liquid processing jig and configured to perform a predetermined processing on the workpiece by the processing liquid;
a liquid supplying unit configured to supply the processing liquid to the liquid processing unit;
a liquid supplying channel configured to connect the liquid supplying unit and the liquid processing unit and supply the processing liquid from the liquid supplying unit to the liquid processing unit; and
a liquid discharging channel configured to discharge the processing liquid from the liquid processing unit,
the liquid processing method comprises:
disposing the liquid processing jig such that the liquid processing unit faces the processing region of the workpiece; and
causing a processing liquid to flow from the liquid supplying unit to the liquid discharging channel by a capillary phenomenon so as to perform the predetermined processing on the workpiece by the processing liquid while the processing liquid is flowing.

13. The liquid processing method of claim 12, wherein the liquid processing jig further includes:
a liquid discharging unit which is connected to one end of the liquid discharging channel and discharges the processing liquid from the liquid processing unit, and
wherein in the processing process, the liquid discharging unit has a predetermined volume which accommodates the processing liquid and absorbs the processing liquid through the liquid discharging channel by the capillary phenomenon.

14. The liquid processing method of claim 12, wherein the liquid processing jig further includes:
an electrode configured to apply a voltage to the processing liquid of the liquid processing unit, and
wherein the predetermined processing performed in the processing process is an electrolytic processing.

15. The liquid processing method of claim 12, wherein the liquid processing unit includes a hydrophilic region having hydrophilicity.

16. The liquid processing method of claim 12, wherein in the processing process, different processing liquids are continuously supplied from the liquid supplying unit so that different processings are continuously performed in the liquid processing unit.
